(19) United States
(12) Patent Application Publication
(10) Pub. No.: US 2009/0290492 A1
(43) Pub. Date: Nov. 26, 2009

(54) METHOD AND APPARATUS TO INDEX NETWORK TRAFFIC META-DATA

(76) Inventors: Matthew Scott Wood, Salt Lake City, UT (US); Paal Tveit, Salt Lake City, UT (US); Brian Edginton, West Jordan, UT (US); Steve Shillingford, Lindon, UT (US); James Brown, Lindon, UT (US)

Correspondence Address: DORSEY & WHITNEY, LLP;INTELLECTUAL PROPERTY DEPARTMENT, 370 SEVENTEENTH STREET, SUITE 4700, DENVER, CO, 80202-5647, US

(21) Appl. No.: 12/126,656

(22) Filed: May 23, 2008

(51) Int. Cl. G01R 31/08

(52) U.S. Cl. 370/235

(57) ABSTRACT

A method, system, and apparatus for indexing network traffic meta-data is disclosed. In one embodiment, a method includes identifying a packet having a header and a payload in a flow of a data through a network, classifying the header of the packet in a type of the header, determining an algorithm to extract a meta-data (e.g., which may be stored in a database of the storage device, and the storage device may be limited in a storage capacity) having information relevant to network traffic visibility based on the type of the header, extracting the meta-data from the header, and streaming the meta-data to a storage device. The method may include applying a last recently used algorithm to discard information from the storage device when storage device is limited in the storage capacity. The method may also include determining that the type of the header is an Ethernet header.

### FIELD OF TECHNOLOGY

This disclosure relates generally to an enterprise method, a technical field of software, hardware and/or networking technology, and in one example embodiment, to method, system and apparatus to index network traffic meta-data.

### BACKGROUND

An entity (e.g., a corporation, a university, an institution, a government, etc.) may enable individuals (e.g., employees) to access a content (e.g., a website, a document, a multimedia clip, etc.) through a network (e.g., a local area network, a wide area network, etc.) that is at least partially controlled by the entity (e.g., through a firewall, a gateway, the local area network, an access point, etc). The individuals may utilize an infrastructure (e.g., routers, servers, switches, data processing systems, etc.) of the entity when accessing the content through the network.

The entity may have a set of rules (e.g., policies, procedures, regulations, security protocols, preferences, etc.) that govern how the network is to be used by the individuals when they access the network through the infrastructure. For example, the set of rules may be designed by the entity to protect security of information generated by employees of the entity (e.g., trade secrets being transmitted to competitors through web-based email systems). Alternatively, the set of rules may help to maintain productivity levels when the employees are at work (e.g., minimize non-work related web surfing). In other instances, the set of rules may help to ensure that a prohibited content (e.g., an unauthorized website) is not accessed by the individuals through the network controlled by the entity.

The individuals may not store any information on a storage device associated with the network controlled by the entity (e.g., local storage, local server) when breaching the set of rules (e.g., trade secrets transmitted to competitors through web-based email systems, non-work related web surfing, viewing the unauthorized website). Therefore, a network management system (e.g., backup systems, monitoring systems) may not be able to determine that the set of rules were breached. Furthermore, the network management system may not be able to determine which of the individuals breached the set of rules and/or when a breach occurred. As a result, security of the network controlled by the entity may be compromised. This may cost the entity money, time, and/or may lead to adverse legal and/or regulatory consequences.

### SUMMARY

A method, system, and apparatus for indexing network traffic metadata is disclosed. In one aspect, a method includes identifying a packet having a header and a payload in a flow of a data through a network, classifying the header of the packet in a type of the header, determining an algorithm to extract a meta-data having information relevant to network traffic visibility based on the type of the header, extracting the meta-data from the header, and streaming the meta-data to a storage device.

The meta-data may be stored in a database of the storage device. The storage device may be limited in a storage capacity (e.g., to 16 terabytes of data). The method may include applying a last recently used algorithm to discard information from the storage device when storage device is limited in the storage capacity. In addition, the method may include determining that the type of the header is an Ethernet header. The method may extract an Ethernet source address, an Ethernet destination address, and/or an Ethernet protocol from the Ethernet header as the meta-data of the Ethernet header. The method may associate the flow of the data through the network to a physical computing device associated with a user through the meta-data of the Ethernet header.

The method may include determining that the type of the header is an IPv4 internet protocol header (e.g., may be an IPv4 internet protocol header and/or an IPv6 internet protocol header). The method may extract a source IP address, an IP flag, a header length, an IP protocol, an IP options (e.g., out of bound messages, may depend on application), and a payload length from the IPv4 internet protocol header as the meta-data of the IPv4 internet protocol header. The method may determine which entity on the network (e.g., which website, which server, etc.) was accessed through the meta-data of the IPv4 internet protocol header. The method may determine how much total traffic was sent by a particular user of the network in a session by analyzing the meta-data of the IPv4 internet protocol header and other IPv4 internet protocol headers.

The method may determine that the type of the header is an IPv6 internet protocol header. The method may extract a source IP address, a destination IP address, a next header, and/or a payload length from the IPv6 internet protocol header as the meta-data of the IPv6 internet protocol header. The method may determine which entity on the network (e.g., which website, which server, etc.) was accessed through the meta-data of the IPv6 internet protocol header. The method may determine how much total traffic was sent by a particular user of the network in a session by analyzing the meta-data of the IPv6 internet protocol header and/or other IPv6 internet protocol headers.

The method may include determining that the type of the header is a transfer control protocol (TCP) header. The method may extract a source port, a destination port, a sequence number, an acknowledgement number, a TCP flag and a TCP option from the TCP header as the meta-data of the TCP header. The method may determine what kind of activity a particular user engaged in (e.g., web traffic, ftp, instant message traffic, etc.) through an analysis of the meta-data of the TCP header and other headers. The method may permit a reconstruction of an artifact (e.g., a file, a photo, etc.) through an analysis of the meta-data of the TCP header.

The method may include determining that the type of the header may be a user datagram protocol (UDP) header. The method may extract a source port, a destination port, a sequence number, and/or a payload length from the UDP header as the meta-data of the UDP header. The method may determine that a particular user engaged in (e.g., one line game playing, name server lookups, hacking, etc.) an unauthorized activity through an analysis of the meta-data of the UDP header and/or other headers. The method may permit a reconstruction of an artifact (e.g., a file, a photo, etc.) through an analysis of the meta-data of the UDP header.

In addition, the method may also include determining that the type of the header is an address resolution protocol (ARP) header. The method may extract a broadcast data from the ARP header as the meta-data of the ARP header. The method may determine that a particular user engaged in (e.g., ARP poisoning, etc.) an unauthorized activity through an analysis of the meta-data of the ARP header and/or other headers. The method may reconstruct the unauthorized activity (e.g., for attack prevention and/or attack detection) through an analysis of the meta-data of the ARP header.

The method may also include storing the meta-data and/or other meta-data of the flow of network data based on a compliance requirement (e.g., CALEA). The data of the network flows through a local area network.

In another aspect, the method includes identifying a packet having a header and a payload in a flow of a data through a network, classifying the header of the packet in a type of the header, determining an algorithm to extract a meta-data having information relevant to network traffic visibility based on the type of the header, extracting the meta-data from the header, determining that a storage device does not have capacity to store the meta-data, and discarding a last recently used data when the storage device does not have capacity to store the meta-data such that a sliding window is formed in the storage device that discards the last recently used data when making room for the meta-data and future meta-data.

The method may include streaming the meta-data to a storage device. The meta-data may be stored in a database of the storage device. The storage device may be limited in a storage capacity (e.g., to 16 terabytes of data).

In addition, the method may include determining that the type of the header may be an Ethernet header. The method may extract any one of an Ethernet source address, an Ethernet destination address, and/or an Ethernet protocol from the Ethernet header as the meta-data of the Ethernet header. The method may associate the flow of the data through the network to a physical computing device associated with a user through the meta-data of the Ethernet header.

In yet another aspect, a visibility module include an analysis module to analyze a packet having a header and a payload in a flow of a data through a network, a type module to classify the header of the packet in a type of the header, an classification module to determine an algorithm to extract a meta-data having information relevant to network traffic visibility based on the type of the header, a extraction module to extract the meta-data from the header, and a streaming module to transfer the meta-data to a storage device.

The meta-data may be stored in a database of the storage device. The storage device may be limited in a storage capacity (e.g., to 16 terabytes of data). The visibility module may include a last recently used data module to apply a last recently used algorithm to discard information from the storage device when storage device may be limited in the storage capacity. The data of the network may flow through a local area network. The visibility module may be a storage appliance coupled to a gateway (e.g., router) of the local area network.

The methods, systems, and apparatuses disclosed herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a system view illustrating a flow of data between an external source and a visibility module, according to one embodiment.

FIG. 2 is a structural view of a packet in a flow, according to one embodiment.

FIG. 3 is an exploded view of a visibility module, according to one embodiment.

FIG. 4 is a table view illustrating a header, a meta-data, extraction method, and a sequence number, etc., according to one embodiment.

FIG. 5 is a diagrammatic system view of a data processing system in which any of the embodiments disclosed herein may be performed, according to one embodiment.

FIG. 6A is a process flow of identifying a packet having a header and a payload in a flow of a data through a network, according to one embodiment.

FIG. 6B is a continuation of process flow of FIG. 6A, illustrating additional operations, according to one embodiment.

FIG. 6C is a continuation of process flow of FIG. 6B, illustrating additional operations, according to one embodiment.

FIG. 6D is a continuation of process flow of FIG. 6C, illustrating additional operations, according to one embodiment.

FIG. 7A is a process flow of associating the flow of the data to the network to a physical computing device associated with a user through the meta-data of the header, according to one embodiment.

FIG. 7B is a continuation of process flow of FIG. 7A, illustrating additional operations, according to one embodiment.

Other features of the present embodiments will be apparent from the accompanying drawings and from the detailed description that follows.

### DETAILED DESCRIPTION

A method, apparatus, and system for indexing network traffic metadata are disclosed. In the following description, for the purposes of explanation, numerous specific details are set forth in order to provide a thorough understanding of the various embodiments. It will be evident, however to one skilled in the art that the various embodiments may be practiced without these specific details.

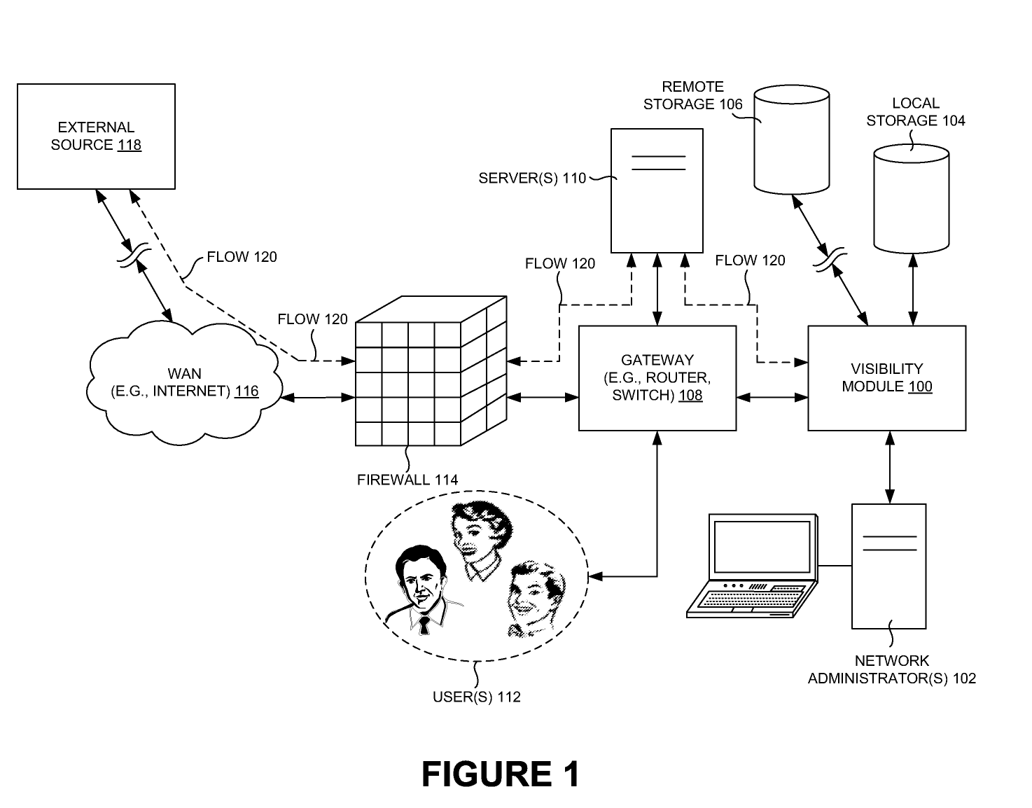

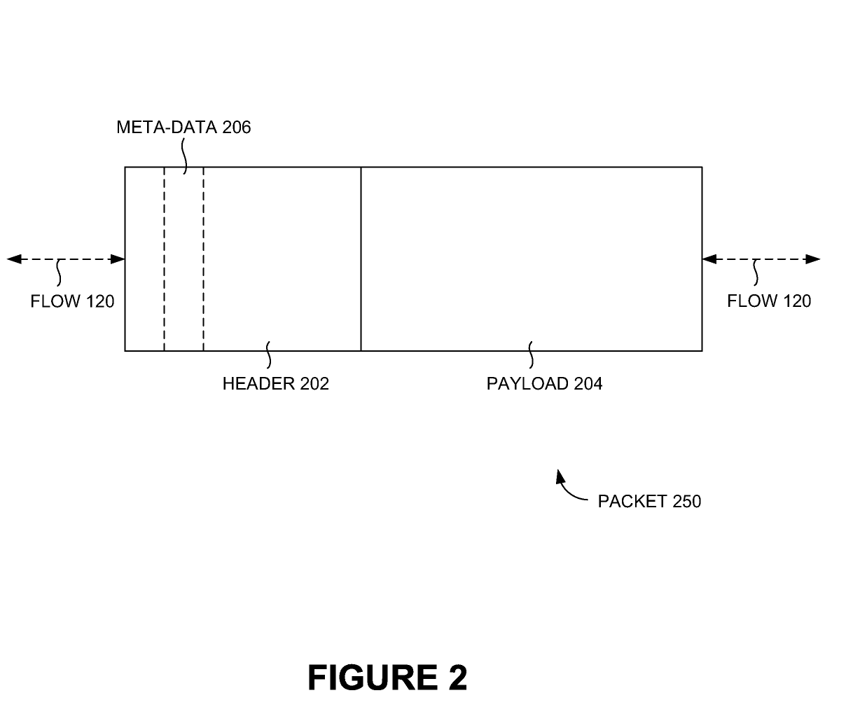

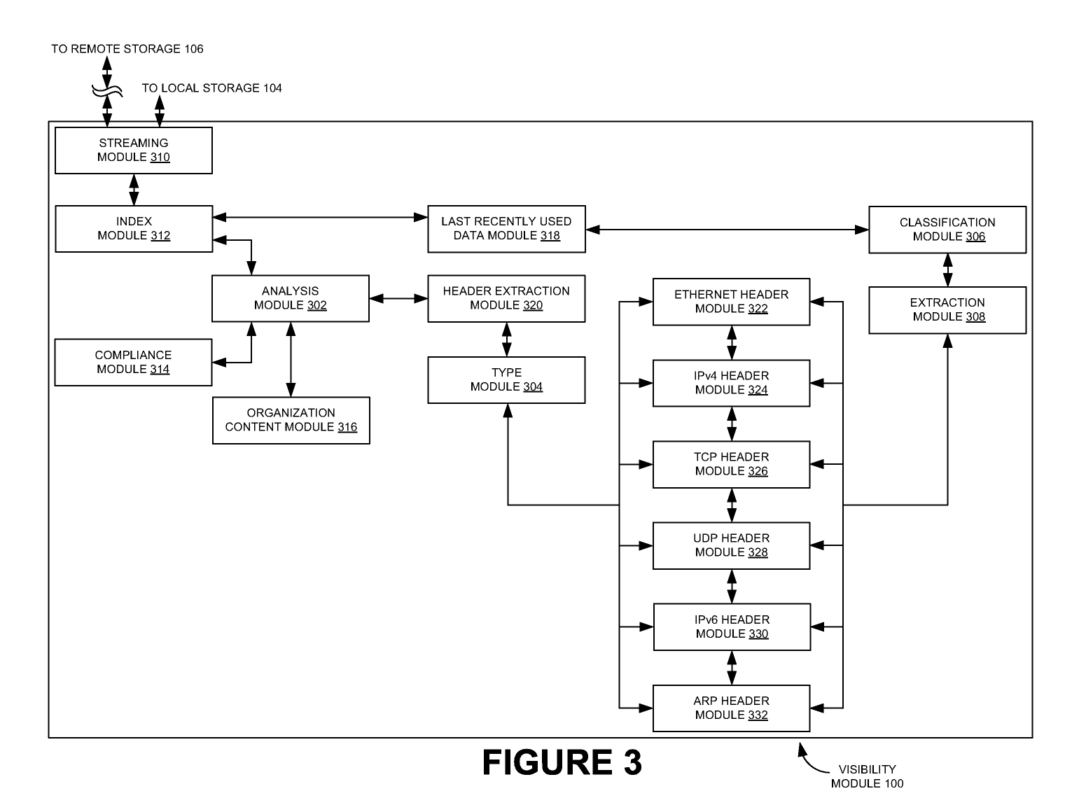

In one embodiment, a method includes identifying a packet (e.g., the packet 250 of FIG. 2) having a header (e.g., the header 202 of FIG. 2) and a payload (e.g., the payload 204 of FIG. 2) in a flow (e.g., the flow 120 of FIG. 1) of a data through a network, classifying (e.g., using the type module 304 of FIG. 3) the header 202 of the packet 250 (e.g., that may include data information such as source, destination, etc.) in a type of the header 202 (e.g., that may include instructions about the data carried by the packet), determining (e.g., using the classification module 306 of FIG. 3) an algorithm (e.g., a logical process by which meta-data can be extracted) to extract a meta-data (e.g., the meta-data 206 of FIG. 2) having information relevant to network traffic visibility based on the type of the header 202, extracting (e.g., using the extraction module 308 of FIG. 3) the meta-data 206 from the header 202, and streaming the meta-data 206 to a storage device (e.g., the local storage 104 and the remote storage 106 of FIG. 1).

In another embodiment, a method include 'es identifying a packet (e.g., the packet 250 of FIG. 2) having a header (e.g., the header 202 of FIG. 2) and a payload (e.g., the payload 204 of FIG. 2) in a flow (e.g., the flow 120 of FIG. 1) of a data (e.g., the meta-data, etc.) through a network, classifying (e.g., the type module 304 of FIG. 3) the header 202 of the packet 250 in a type of the header 202, determining (e.g., the classification module 306 of FIG. 3) an algorithm to extract a meta-data (e.g., the meta-data 206 of FIG. 2) having information relevant to network traffic visibility based on the type of the header 202, extracting (e.g., using the extraction module 308 of FIG. 3) the meta-data 206 from the header 202, determining that a storage device (e.g., the local storage and the remote storage) does not have capacity to store the meta-data 206 (e.g., as illustrated in the visibility module 100 of FIG. 1), and discarding a last recently used data (e.g., using the visibility module 100 of FIG. 1) when the storage device does not have capacity to store the meta-data 206 such that a sliding window is formed in the storage device that discards (e.g., using the visibility module 100 of FIG. 1) the last recently used data when making room for the meta-data 206 and future meta-data.

In yet another embodiment, a visibility module (e.g., the visibility module 100 of FIG. 1) includes an analysis module (e.g., the analysis module 302 of FIG. 3) to analyze a packet (e.g., the packet 250 of FIG. 2) having a header (e.g., the header 202 of FIG. 2) and a payload (e.g., the payload 204 of FIG. 2) in a flow (e.g., the flow 120 of FIG. 1) of a data (e.g., the meta-data) through a network, a type module (e.g., the type module 304 of FIG. 3) to classify the header 202 of the packet 250 in a type of the header 202, an classification module (e.g., the classification module 306 of FIG. 3) to determine an algorithm to extract a meta-data (e.g., the meta-data 206 of FIG. 2) having information relevant to network traffic visibility based on the type of the header 202, an extraction module (e.g., the extraction module 308 of FIG. 3) to extract the meta-data 206 from the header 202, and a streaming module (e.g., the streaming module 310 of FIG. 3) to transfer the meta-data 206 to a storage device (e.g., the local storage 104 and the remote storage 106 of FIG. 1).

FIG. 1 is a system view illustrating a flow of data between an external source and a visibility module, according to one embodiment. Particularly, FIG. 1 illustrates a visibility module 100, a network administrator(s) 102, a local storage 104, a remote storage 106, a gateway 108, a server(s) 110, an user(s) 112, a firewall 114, a WAN 116, an external source 118, and a flow 120, according to one embodiment.

The visibility module 100 may be an appliance coupled to a gateway (e.g., router, etc.) that may store/discard a meta-data information from a storage device in a local area network. The network administrator(s) 102 may be an person/software who manages (e.g., may include network security, installing new applications, distributing software upgrades, monitoring daily activity, developing a storage management program and/or providing for routine backups, etc.) a local area communications network (LAN) within an entity. The local storage 104 may be a storage medium (e.g., hard disk, flash drive, etc.) that may process (e.g., store, retrieve, etc.) the data (e.g., meta-data, information, etc.) communicated by the visibility module 100.

The remote storage 106 may be a storage medium (e.g., server, etc.) that manages (e.g., stores, retrieves, etc.) the data (e.g., information associated to the headers such as meta-data, etc.) communicated by the visibility module 100. The gateway 108 (e.g., router, switch, bridge, etc.) may interconnect (e.g., by protocol mapping/translation) external networks to the local area network where the networks may have different network protocol technologies.

The server(s) 110 (e.g., web servers, e-mail servers, etc.) may be a computer, application program, etc. that may accept connections in order to service requests by sending back responses to the client devices.

The user(s) 112 (e.g., employees, clients, etc.) may be individual(s) who may communicate with the server 110 for processing (e.g., transferring, receiving, etc.) data (e.g., information on internet) through gateway 108 (e.g., router, switch) associated with the server. The firewall 114 may be a system (e.g., may be implemented in hardware, software and/or combination of both) that secures a network, shielding it from access by unauthorized users and may also control (e.g., restrict) the data from flowing out/coming in to the network. The WAN 116 (e.g., internet) may connect LAN's (e.g., using “long haul” communication carriers such as Sprint* and UUNET*) around the world. The external source 118 may be a computer, server, mobile device, to which the user(s) 112 may communicate with. The flow 120 may be a path through which the data may stream (e.g., from and/or towards the target machine).

In example embodiment, FIG. 1 may illustrate the flow of data between the external source (e.g., may be remote computer, server, mobile device, etc.) to the visibility module 100. The data may stream from external sources through the WAN 116, the firewall 114, the gateway 108, the server 110 to the visibility module 100, the user(s) 112, storage devices and/or the network administrator(s) 102. The user(s) 112 may communicate with the server 110 through the gateway 108 to connect to the external source 118. The network administrator(s) 102 may communicate with the visibility module 100 to monitor the communication of data that the user(s) 112 are communicating with the external source 118. The visibility module 100 may monitor the content of the data which the user(s) are communicating with the external source 118 by analyzing the header of the packet (e.g., which may include the meta-data). The data content (e.g., which may include meta-data) may be stored/discard by the visibility module 100 in the storage mediums (e.g., the local storage 104 and/or the remote storage 106).

In one embodiment, the meta-data 206 may be stored (e.g., using the visibility module 100 of FIG. 1) in a database of the storage device. The storage device may be limited in the storage capacity (e.g., to 16 terabytes of data). A last recently used algorithm may be applied to discard (e.g., using the visibility module 100 of FIG. 1) information from the storage device when storage device is limited in the storage capacity (e.g., may be 16 terabytes of data). The meta-data 206 and/or other meta-data of the flow 120 of network data based on a compliance requirement (e.g., CALEA) may be stored (e.g., using the visibility module 100 of FIG. 1). The data of the network may flow through the local area network (e.g., as illustrated in FIG. 1).

The meta-data 206 may be stored (e.g., using the visibility module 100 of FIG. 1) in a database of the storage device. The storage device may be limited in a storage capacity (e.g., to 16 terabytes of data). The last recently used data module 318 may apply (e.g., the visibility module 100 of FIG. 1) a last recently used algorithm to discard information from the storage device when storage device may be limited in the storage capacity. The data of the network may flow through the local area network. The visibility module 100 may be a storage appliance coupled to a gateway (e.g., router) of the local area network.

FIG. 2 is a structural view of a packet 250 in a flow, according to one embodiment. Particularly, FIG. 2 illustrates the flow 120, a packet 250, a header 202, a payload 204, and a meta-data 206, according to one embodiment.

The packet 250 may be a logical group (e.g., large data broken into small units for transmitting over network) of data of a certain size in bytes which may include header and the payload. The header 202 may have instructions (e.g., length of packet, packet number, synchronization, protocol, destination address, originating address, meta-data, etc.) associated to the data carried by the packet. The payload 204 may be a part of the packet that carries actual data. The meta-data 206 may be the data that describes a dataset to allow others to find and/or evaluate it (e.g., schema, table, index, view and column definitions).

In example embodiment, FIG. 2 illustrates the structure of the packet which includes the header 202 and the payload 204. The header may include information such as meta-data 206, instructions, etc. The packet may be communicated between the user(s) 112 and the external source 118 in the flow 120.

FIG. 3 is an exploded view of a visibility module 100, according to one embodiment. Particularly, FIG. 3 illustrates to local storage 104, to remote storage 106, an analysis module 302, a type module 304, a classification module 306, an extraction module 308, a streaming module 310, an index module 312, a compliance module 314, an organization content module 316, a last recently used data module 318, a header extraction module 320, an Ethernet header module 322, an IPv4 header module 324, a TCP header module 326, a UDP header module 328, an IPv6 header module 330, and an ARP header module 332, according to one embodiment.

The analysis module 302 may analyze (e.g., check, verify, etc.) the packet 250 having a header 202 and a payload 204 in a flow of the data through a network. The type module 304 may classify (e.g., identify) the header 202 of the packet 250 to associated category (e.g., IPv4 header, IPv6 header, TCP header, etc.). The classification module 306 may determine an algorithm (e.g., a suitable logical technique) to extract the meta-data 206 having information relevant to network traffic visibility based on the type of the header (e.g., IPv4 header, IPv6 header, TCP header, etc.). The extraction module 308 may extract the meta-data 206 from the header 202. The streaming module 310 may transfer the meta-data 206 to the storage device (e.g., the local storage 104 and/or the remote storage 106).

The index module 312 may communicate (e.g., transmit, receive, etc.) the data packets based on index (e.g., logical sequences). The compliance module 314 may check for the compliance requirement for storing meta-data and other meta-data in the storage devices. The organization content module 316 may check for organization content in the data that may be communicated from/to the external source 118. The last recently used data module 318 may apply a last recently used algorithm to discard information from the storage device when storage device is limited in the storage capacity. The header extraction module 320 may extract the header content of the data packet (e.g., that may contain meta-data and other meta-data).

The Ethernet header module 322 may use the meta-data of the Ethernet header to associate the flow of the data through the network to a physical computing device associated with a user. The IPv4 header module 324 may determine which entity on the network (e.g., which website, which server, etc.) was accessed through the meta-data and how much total traffic was sent by a particular user of the network in a session by analyzing the meta-data in the IPv4 header. The TCP header module 326 may determine what kind of activity a particular user engaged in (e.g., web traffic, ftp, instant message traffic, etc.) and may permit a reconstruction of an artifact (e.g., a file, a photo, etc.) through an analysis of the meta-data of the TCP header.

The UDP header module 328 may determine that a particular user engaged in (e.g., one line game playing, name server lookups, hacking, etc.) an unauthorized activity and may permit a reconstruction of an artifact (e.g., a file, a photo, etc.) through an analysis of the meta-data of the UDP header and other header. The IPv6 header module 330 may determine which entity on the network (e.g., which website, which server, etc.) was accessed through the meta-data and how much total traffic was sent by a particular user of the network in a session by analyzing the meta-data in the IPv6 header. The ARP header module 332 may determining that a particular user engaged in (e.g., ARP poisoning, etc.) an unauthorized activity and may enable reconstructing the unauthorized activity (e.g., for attack prevention and attack detection) through an analysis of the meta-data of the ARP header.

In example embodiment, FIG. 3 illustrates the analysis module 302 that may communicate with the organization content module 316, the header extraction module 320, the index module 312 and/or the compliance module 314. The type module 304 may communicate with the Ethernet header module 322, the IPv4 header module 324, TCP header module 326, UDP header module 328, IPv6 header module 330, and/or ARP header module 332. The classification module 306 may communicate with the extraction module 308, and/or the last recently used data module 318. The streaming module 310 that may communicate with the index module 312. The streaming module 310 may stream the data packets to/from the remote storage 106 and/or the local storage 104.

In one embodiment, the packet 250 having the header 202 and the payload 204 may be identified in the flow 120 of the data (e.g., may include the meta-data, etc.) through a network. The header 202 of the packet 250 (e.g., may be Ethernet header, IPV4 header, IPv6 header, UDP header, etc.) may be classified (e.g., using the type module 304 of FIG. 3) in a type of the header 202. An algorithm may be determined (e.g., using the classification module 306 of FIG. 3) to extract the meta-data 206 having information relevant to network traffic visibility based on the type of the header 202. The meta-data 206 may be extracted (e.g., using the extraction module 308 of FIG. 3) from the header 202. The meta-data 206 may be streamed (e.g., using the streaming module 310 of FIG. 3) to the storage device (e.g., the local storage 104 and/or the remote storage 106 of FIG. 1).

It may be determined (e.g., using the type module 304 of FIG. 3) that the type of the header 202 is the Ethernet header. An Ethernet source address, an Ethernet destination address, and/or an Ethernet protocol may be extracted (e.g., using the extraction module 308 of FIG. 3) from the Ethernet header as the meta-data 206 of the Ethernet header. The flow 120 of the data may be associated through the network to a physical computing device associated with the user 112 through the meta-data 206 of the Ethernet header. It may be determined (e.g., using the type module 304 of FIG. 3) that the type of the header 202 is an IPv4 internet protocol header.

A source IP address, a destination IP address, an IP flag, a header length, an IP protocol, an IP options (e.g., out of bound messages, may depend on application), and a payload length may be extracted (e.g., using the extraction module 308 of FIG. 3) from the internet protocol header as the meta-data 206 of the internet protocol header. It may be determined which entity on the network (e.g., which website, which server, etc.) may be accessed through the meta-data 206 of the IPv4 internet protocol header (e.g., using the IPv4 header module 324 of FIG. 3). It may be determined (e.g., using the classification module 306 of FIG. 3) how much total traffic may be sent by a particular user of the network in a session by analyzing the meta-data 206 of the IPv4 internet protocol header and/or other IPv4 internet protocol headers (e.g., using the IPv4 header module 324 of FIG. 3).

It may be determined that the type of the header may be an IPv6 internet protocol header (e.g., using the type module 304 of FIG. 3). A source IP address, a destination IP address, a next header, and/or a payload length may be extracting from the IPv6 internet protocol header as the meta-data of the IPv6 internet protocol header (e.g., using the IPv6 header module 330 of FIG. 3). It may be determined which entity on the network (e.g., which website, which server, etc.) was accessed through the meta-data of the IPv6 internet protocol header (e.g., using the IPv6 header module 330 of FIG. 3). It may be determined how much total traffic was sent by a particular user of the network in a session by analyzing the meta-data of the IPv6 internet protocol header and other IPv6 internet protocol headers (e.g., using the IPv6 header module 330 of FIG. 3).

It may be determined that the type of the header 202 may be a transfer control protocol (TCP) header (e.g., using the type module 304 of FIG. 3). A source port, a destination port, a sequence number, a payload length, an acknowledgement number, a TCP flag, and a TCP option and/or a payload length may be extracted (e.g., using the extraction module 308 of FIG. 3) from the TCP header as the meta-data 206 of the TCP header. It may be determined what kind of activity a particular user engaged in (e.g., web traffic, ftp, instant message traffic, etc.) through the analysis of the meta-data 206 of the TCP header and/or other headers (e.g., using the TCP header module 326 of FIG. 3). A reconstruction of an artifact (e.g., a file, a photo, etc.) may be permitted through an analysis (e.g., may be analyzing the TCP header using the TCP header module 326 of FIG. 3) of the meta-data 206 of the TCP header.

It may be determined that the type of the header may be the user datagram protocol (UDP) header. A source port, a destination port, a sequence number, and/or a payload length may be extracted (e.g., using the extraction module 308 of FIG. 3) from the UDP header as the meta-data 206 of the UDP header. It may be determined that a particular user engaged in (e.g., one line game playing, name server lookups, hacking, etc.) an unauthorized activity through an analysis of the meta-data 206 of the UDP header and other headers (e.g., using the UDP header module 328 of FIG. 3). A reconstruction of an artifact (e.g., a file, a photo, etc.) may be permitted through an analysis (e.g., may be analyzing the UDP header using the UDP header module 328 of FIG. 3) of the meta-data 206 of the UDP header.

It may be determined (e.g., using the type module 304 of FIG. 3) that the type of the header 202 may be an address resolution protocol (ARP) header. A broadcast data may be extracted (e.g., using the extraction module 308 of FIG. 3) from the ARP header as the meta-data of the ARP header. It may be determined that a particular user engaged in (e.g., ARP poisoning, etc.) an unauthorized activity through an analysis of the meta-data 206 of the ARP header and/or other headers (e.g., using the ARP header module 332 of FIG. 3). The unauthorized activity (e.g., for attack prevention and attack detection) may be reconstructed through the analysis (e.g., may be analyzing the ARP header using the ARP header module 332 of FIG. 3) of the meta-data 206 of the ARP header.

It may be determined that a storage device may not have capacity to store the meta-data 206. A last recently used data may be discarded (e.g., using the last recently used data module 318 of FIG. 3) when the storage device may not have capacity to store the meta-data 206 such that a sliding window may be formed in the storage device that may discard (e.g., using the visibility module 100 of FIG. 1) the last recently used data when making room for the meta-data 206 and/or future meta-data. The meta-data 206 may be streamed (e.g., using the streaming module 310 of FIG. 3) to a storage device.

The analysis module 302 may analyze the packet 250 having the header 202 and/or the payload 204 in the flow 120 of a data through a network. The type module 304 may classify the header 202 of the packet 250 in a type of the header 202. The classification module 306 may determine an algorithm to extract the meta-data 206 may have information relevant to network traffic visibility based on the type of the header 202. The extraction module 308 may extract the meta-data 206 from the header 202. The streaming module 310 may transfer the meta-data 206 to a storage device.

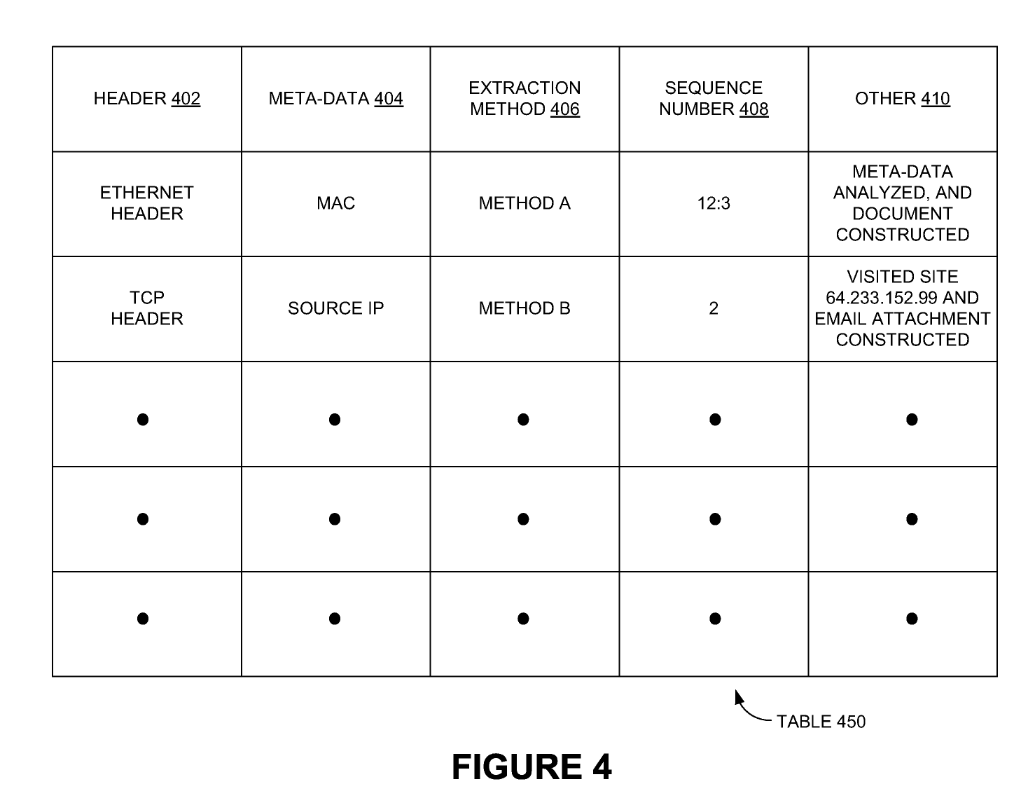

FIG. 4 is a table view illustrating a header, a meta-data, extraction method, and a sequence number, etc., according to one embodiment. Particularly, FIG. 4 illustrates a header field 402, a meta-data field 404, an extraction method field 406, a sequence number field 408, and other field 410, according to one embodiment.

The header field 402 may illustrate various type of headers associated to the data that may be carried by the packet. The meta-data field 404 may illustrate different types of meta-data which may be associated with the header 202. The extraction method field 406 may illustrate different methods (e.g., algorithms) that may be used for extraction of header contents (e.g., meta-data, etc.). The sequence number field 408 may indicate the sequence number of the packet in a set of packets. The other field 410 may illustrate the other aspects associated to the extraction of data.

In example embodiment, FIG. 4 illustrates a table 450. The header field 402 may illustrates the Ethernet header in the first row, and the TCP header in the second row. The meta-data field 404 may illustrate the MAC in the first row, and the source IP in the second row. The extraction method field 406 may illustrate the method A in the first row, and the method B in the second row. The sequence number field 408 may illustrate 12:3 in the first row, and 2 in the second row. The other field 410 may illustrate “meta-data analyzed, and document constructed” in the first row, and “visited site 64.233.152.99 and email attachment constructed” in the second row.

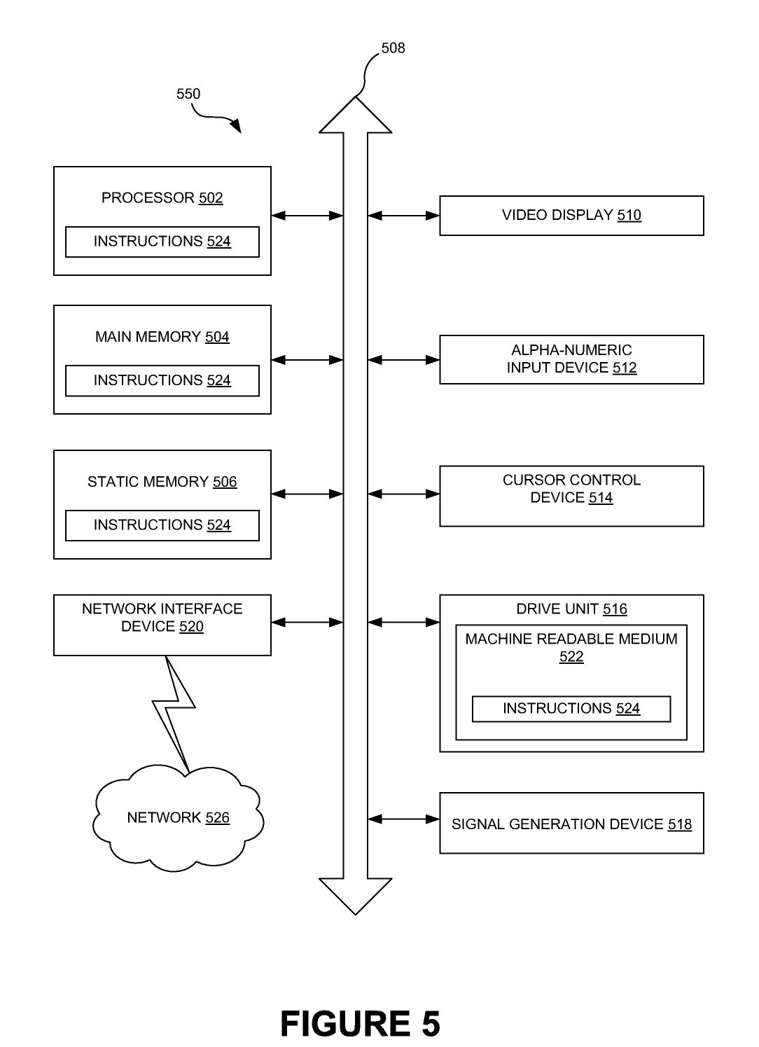

FIG. 5 is a diagrammatic system view of a data processing system in which any of the embodiments disclosed herein may be performed, according to one embodiment. Particularly, the diagrammatic system view 500 of FIG. 5 illustrates a processor 502, a main memory 504, a static memory 506, a bus 508, a video display 510, an alpha-numeric input device 512, a cursor control device 514, a drive unit 516, a signal generation device 518, a network interface device 520, a machine readable medium 522, instructions 524, and a network 526, according to one embodiment.

The diagrammatic system view 500 may indicate a personal computer and/or the data processing system in which one or more operations disclosed herein are performed. The processor 502 may be a microprocessor, a state machine, an application specific integrated circuit, a field programmable gate array, etc. (e.g., Intel® Pentium® processor). The main memory 504 may be a dynamic random access memory and/or a primary memory of a computer system.

The static memory 506 may be a hard drive, a flash drive, and/or other memory information associated with the data processing system. The bus 508 may be an interconnection between various circuits and/or structures of the data processing system. The video display 510 may provide graphical representation of information on the data processing system. The alpha-numeric input device 512 may be a keypad, a keyboard and/or any other input device of text (e.g., a special device to aid the physically handicapped).

The cursor control device 514 may be a pointing device such as a mouse. The drive unit 516 may be the hard drive, a storage system, and/or other longer term storage subsystem. The signal generation device 518 may be a bios and/or a functional operating system of the data processing system. The network interface device 520 may be a device that performs interface functions such as code conversion, protocol conversion and/or buffering required for communication to and from the network 526. The machine readable medium 522 may provide instructions on which any of the methods disclosed herein may be performed. The instructions 524 may provide source code and/or data code to the processor 502 to enable any one or more operations disclosed herein.

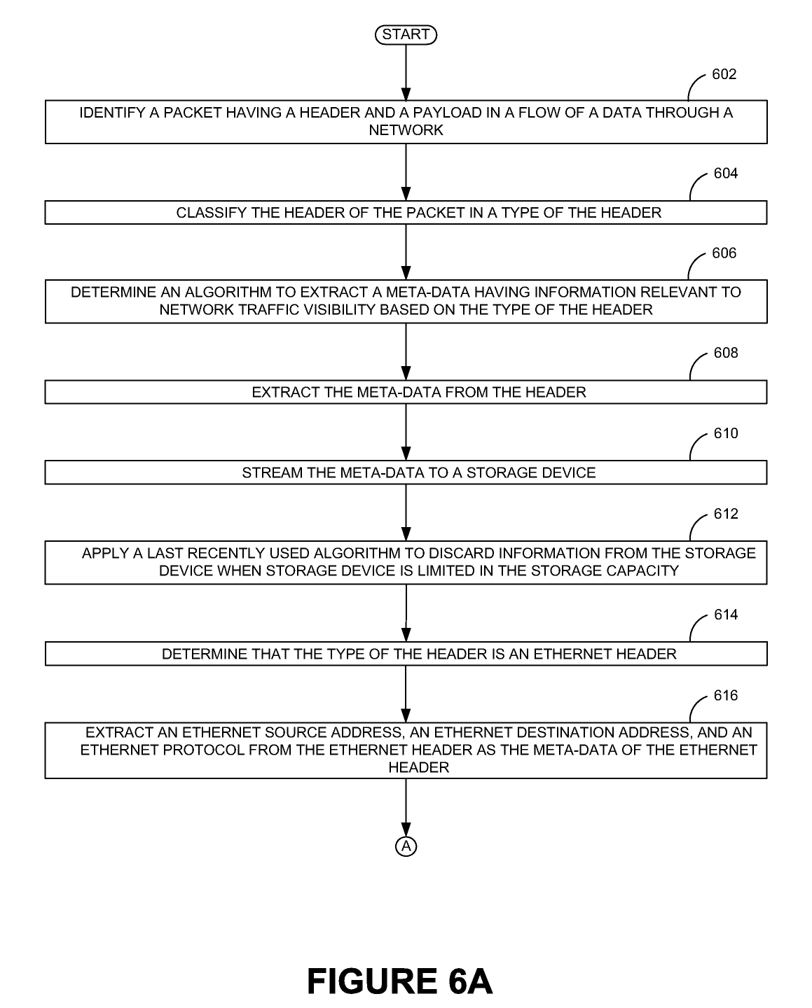

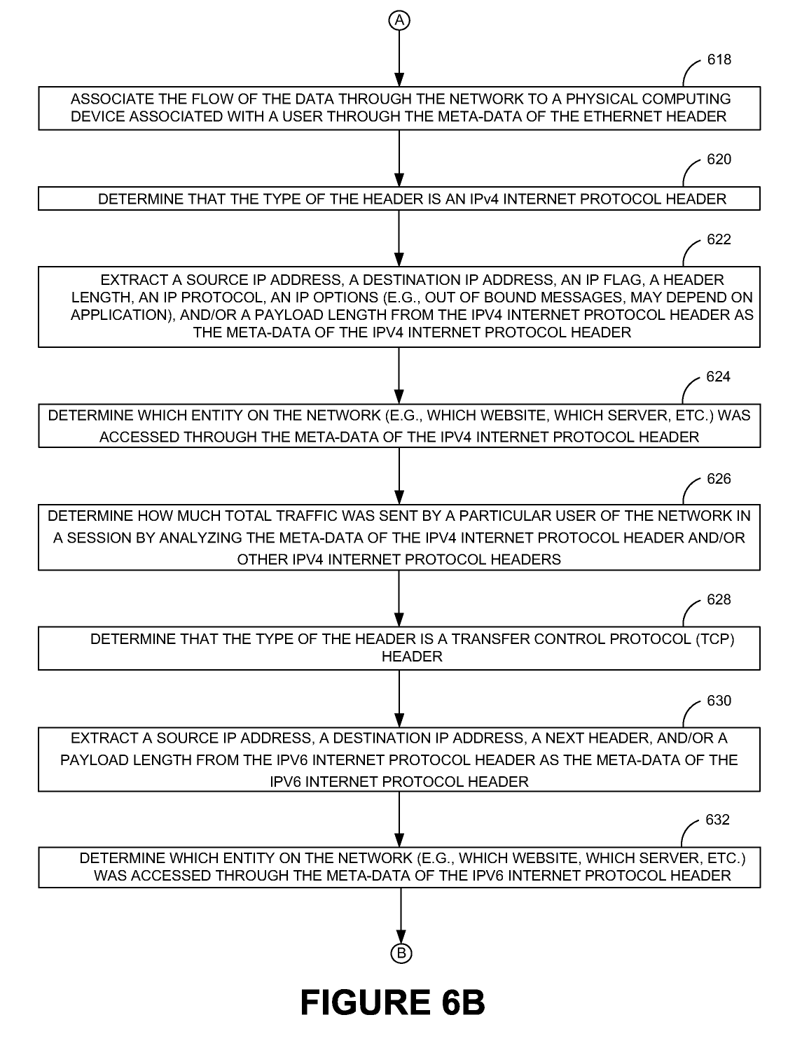

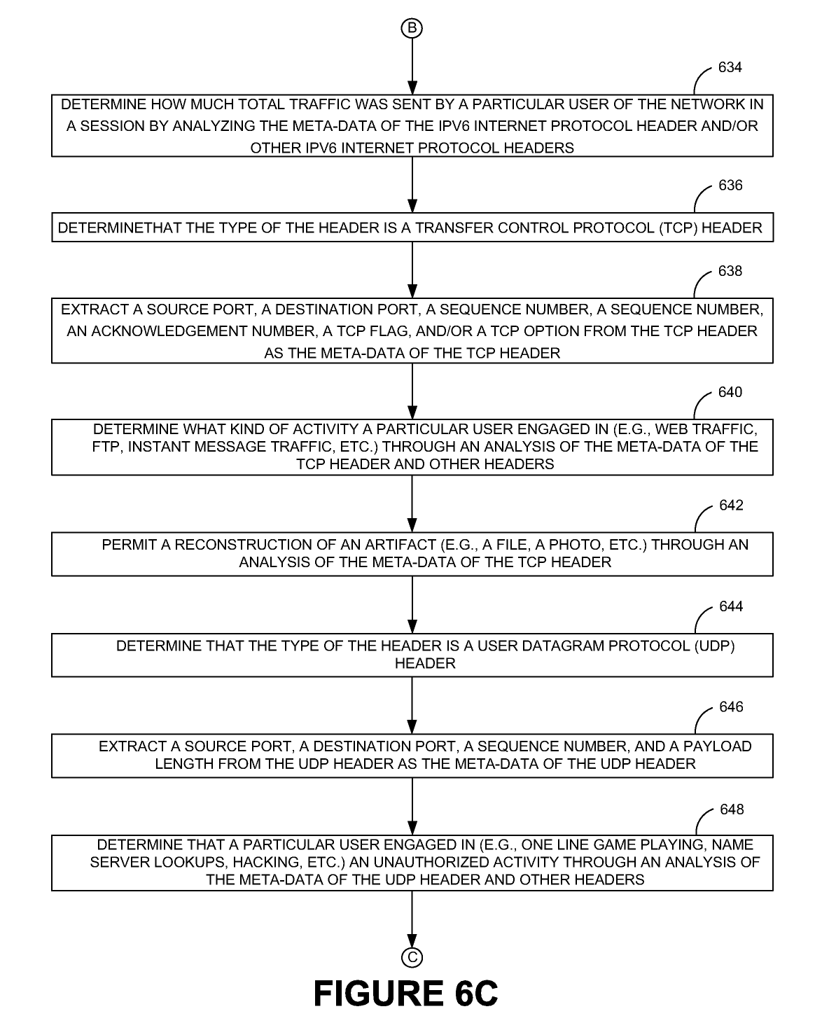

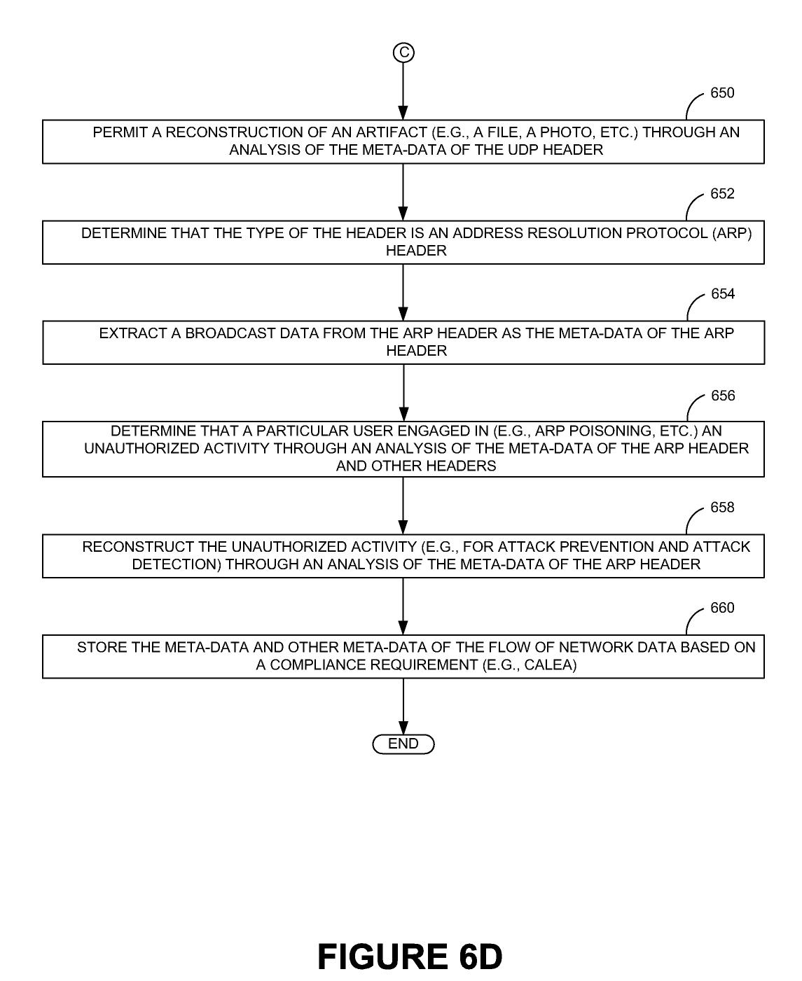

FIG. 6A is a process flow of identifying a packet having a header and a payload in a flow of a data through a network, according to one embodiment. In operation 602, a packet (e.g., the packet 250 of FIG. 2) having a header (e.g., the header 202 of FIG. 2) and a payload (e.g., the payload 204 of FIG. 2) may be identified (e.g., using the analysis module 302 of FIG. 3) in a flow (e.g., the flow 120 of FIG. 1) of a data (e.g., the meta-data) through a network. In operation 604, the header 202 of the packet 250 may be classified (e.g., using the type module 304 of FIG. 3) in a type of the header 202. In operation 606, an algorithm may be determined (e.g., using the classification module 306 of FIG. 3) to extract a meta-data (e.g., the meta-data 206 of FIG. 2) having information relevant to network traffic visibility based on the type of the header 202. In operation 608, the meta-data 206 may be extracted (e.g., using the extraction module 308 of FIG. 3) from the header 202. In operation 610, the meta-data 206 may be streamed (e.g., using the streaming module 310 of FIG. 3) to the storage device (e.g., the local storage 104 and the remote storage 106 as illustrated in FIG. 1).

The meta-data 206 may be stored (e.g., using the visibility module 100 of FIG. 1) in a database of the storage device. The storage device may be limited in a storage capacity (e.g., to 16 terabytes of data). In operation 612, a last recently used algorithm may be applied to discard (e.g., using the last recently used data module 318 of FIG. 3) information from the storage device when storage device is limited in the storage capacity. In operation 614, it may be determined (e.g., using the type module 304 of FIG. 3) that the type of the header 202 may be an Ethernet header.

FIG. 6B is a continuation of process flow of FIG. 6A, illustrating additional operations, according to one embodiment. In operation 616, an Ethernet source address, an Ethernet destination address, and/or an Ethernet protocol may be extracted (e.g., using the extraction module 308 of FIG. 3) from the Ethernet header as the meta-data of the Ethernet header.

FIG. 6B is a continuation of process flow of FIG. 6A, illustrating additional operations, according to one embodiment. In operation 618, the flow 120 of the data may be associated through the network to a physical computing device associated with a user (e.g., the user 112 of FIG. 1) through the meta-data 206 of the Ethernet header.

In operation 620, it may be determined (e.g., using the classification module 306 of FIG. 3) that the type of the header 202 may be an IPv4 internet protocol header. In operation 622, a source IP address, a destination IP address, an IP flag, a header length, an IP protocol, an IP options (e.g., out of bound messages, may depend on application), and/or a payload length may be extracted (e.g., using the extraction module 308 of FIG. 3) from the IPv4 internet protocol header as the meta-data 206 of the IPv4 internet protocol header. In operation 624, it may be determined which entity on the network (e.g., which website, which server, etc.) may be accessed through the meta-data 206 of the IPv4 internet protocol header (e.g., using the IPv4 header module 324 of FIG. 3).

In operation 626, it may be determined (e.g., using the classification module 306 of FIG. 3) how much total traffic may be sent by a particular user of the network in a session by analyzing (e.g., by analyzing the header using the IPv4 header module 324 of FIG. 3) the meta-data 206 of the internet protocol header and/or other internet protocol headers. In operation 628, it may be determined (e.g., using the type module 304 of FIG. 3) that the type of the header may be an IPv6 internet protocol header. In operation 630, a source IP address, a destination IP address, a next header, and/or a payload length may be extracted (e.g., using the extraction module 308 of FIG. 3) from the IPv6 internet protocol header as the meta-data of the IPv6 internet protocol header.

FIG. 6C is a continuation of process flow of FIG. 6B, illustrating additional operations, according to one embodiment. In operation 632, It may be determined which entity on the network (e.g., which website, which server, etc.) may be accessed through the meta-data of the IPv6 internet protocol header (e.g., using the IPv6 header module 330 of FIG. 3). In operation 634, it may be determined how much total traffic may be sent by a particular user of the network in a session by analyzing the meta-data of the IPv6 internet protocol header and/or other IPv6 internet protocol headers (e.g., by analyzing the header using the IPv6 header module 330 of FIG. 3).

In operation 636, it may be determined (e.g., using the type module 304 of FIG. 3) that the type of the header may be a transfer control protocol (TCP) header (e.g., as illustrated in FIG. 3). In operation 638, a source port, a destination port, a sequence number, a sequence number, an acknowledgement number, a TCP flag, and a TCP option may be extracted (e.g., using the extraction module 308 of FIG. 3) from the TCP header as the meta-data of the TCP header.

In operation 640, it may be determined (e.g., using the TCP header module 326 of FIG. 3) what kind of activity a particular user engaged in (e.g., web traffic, ftp, instant message traffic, etc.) through an analysis of the meta-data 206 of the TCP header and/or other headers. In operation 642, a reconstruction of an artifact (e.g., a file, a photo, etc.) may be permitted through an analysis (e.g., using the TCP header module 326 of FIG. 3) of the meta-data 206 of the TCP header. In operation 644, it may be determined (e.g., using the type module 304 of FIG. 3) that the type of the header 202 may be a user datagram protocol (UDP) header. In operation 646, a source port, a destination port, a sequence number, and/or a payload length may be extracted (e.g., using the extraction module 308 of FIG. 3) from the UDP header as the meta-data 206 of the UDP header.

FIG. 6D is a continuation of process flow of FIG. 6C, illustrating additional operations, according to one embodiment. In operation 648, it may be determined (e.g., using the UDP header module 328 of FIG. 3) that a particular user engaged in (e.g., one line game playing, name server lookups, hacking, etc.) an unauthorized activity through an analysis of the meta-data 206 of the UDP header and/or other headers. In operation 650, a reconstruction of an artifact (e.g., a file, a photo, etc.) may be permitted through an analysis (e.g., using the UDP header module 328 of FIG. 3) of the meta-data 206 of the UDP header. In operation 652, it may be determined (e.g., using the type module 304 of FIG. 3) that the type of the header 202 may be an address resolution protocol (ARP) header.

In operation 654, a broadcast data may be extracted (e.g., using the extraction module 308 of FIG. 3) from the ARP header as the meta-data of the ARP header. In operation 656, it may be determined (e.g., using the ARP header module 332 of FIG. 3) that a particular user engaged in (e.g., ARP poisoning, etc.) an unauthorized activity through an analysis of the meta-data of the ARP header and other headers. In operation 658, the unauthorized activity (e.g., for attack prevention and attack detection) may be reconstructed (e.g., using the ARP header module 332 of FIG. 3) through an analysis of the meta-data 206 of the ARP header. In operation 660, the meta-data 206 and/or other meta-data of the flow 120 of network data based on a compliance requirement (e.g., CALEA) may be stored (e.g., using the visibility module 100 of FIG. 1). The data of the network may flow through a local area network (e.g., as illustrated in FIG. 1).

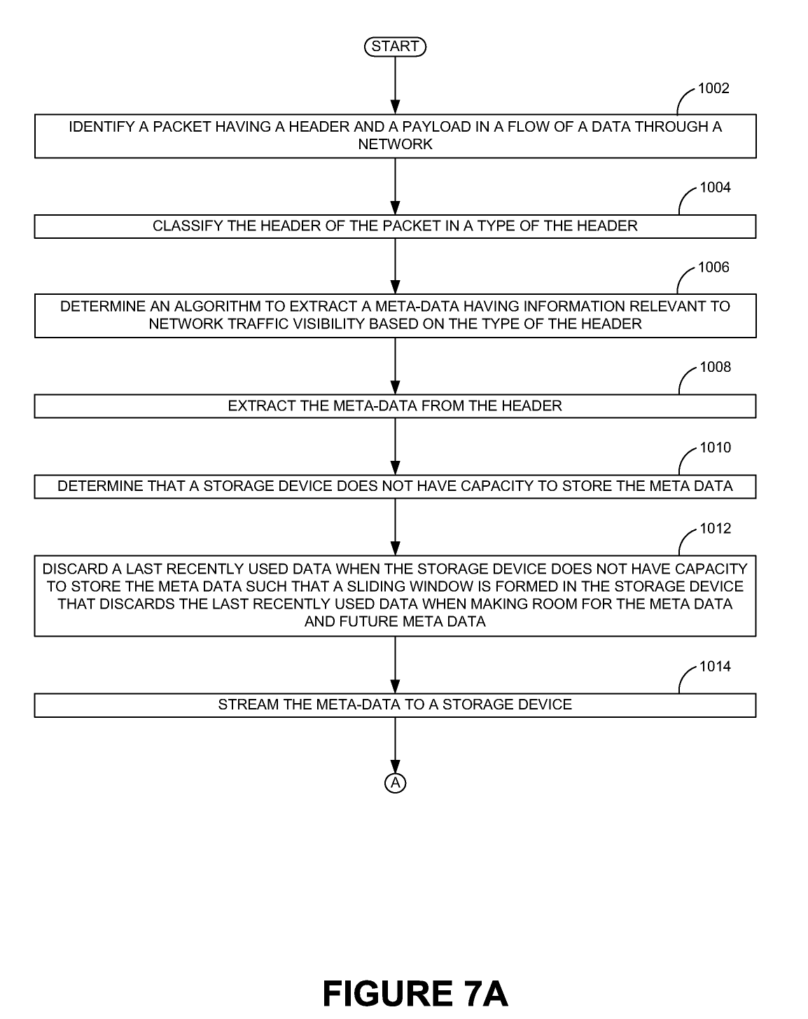

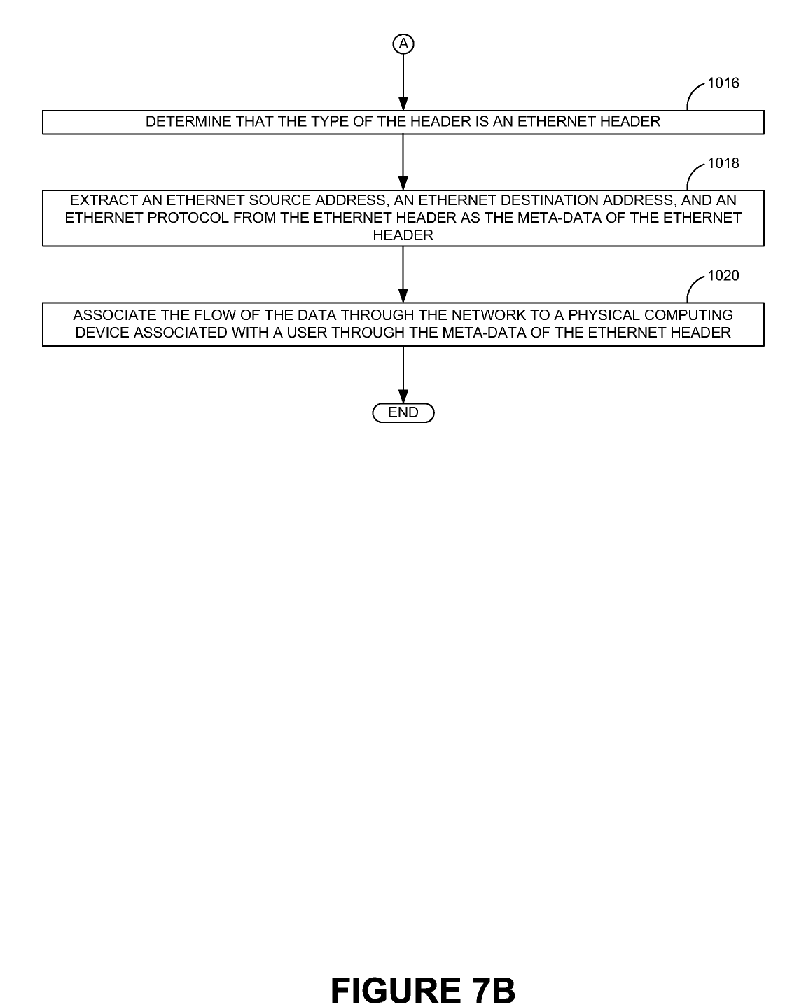

FIG. 7A is a process flow of associating the flow of the data to the network to a physical computing device associated with a user through the meta-data of the header, according to one embodiment. In operation 702, a packet (e.g., the packet 250 of FIG. 2) having a header (e.g., the header 202 of FIG. 2) and/or a payload (e.g., the payload 204 of FIG. 2) in a flow (e.g., the flow 120 of FIG. 1) of a data (e.g., the meta-data, etc.) may be identified (e.g., using the analysis module 302 of FIG. 3) through a network. In operation 704, the header 202 of the packet 250 may be classified (e.g., using the type module 304 of FIG. 3) in a type of the header 202.

In operation 706, an algorithm may be determined (e.g., using the classification module 306 of FIG. 3) to extract a meta-data (e.g., the meta-data 206 of FIG. 2) having information relevant to network traffic visibility based on the type of the header 202. In operation 708, the meta-data 206 may be extracted (e.g., using the extraction module 308 of FIG. 3) from the header 202. In operation 710, it may be determined that a storage device (e.g., the local storage and/or the remote storage) may not have capacity to store (e.g., using the visibility module 100 of FIG. 1) the meta-data 206.

In operation 712, a last recently used data may be discarded (e.g., using the last recently used data module 318 of FIG. 3) when the storage device may not have capacity to store the meta-data 206 such that a sliding window may be formed in the storage device that may discard the last recently used data when making room for the meta-data 206 and/or future meta-data. In operation 714, the meta-data 206 may be streamed to a storage device (e.g., using the streaming module 310 of FIG. 3).

The meta-data 206 may be stored (e.g., using the visibility module 100 of FIG. 1) in a database of the storage device. The storage device may be limited in a storage capacity (e.g., to 16 terabytes of data). In operation 716, it may be determined (e.g., using the type module 304 of FIG. 3) that the type of the header 202 may be an Ethernet header.

FIG. 7B is a continuation of process flow of FIG. 7A, illustrating additional operations, according to one embodiment. In operation 718, an Ethernet source address, an Ethernet destination address, and/or an Ethernet protocol may be extracted (e.g., using the extraction module 308 of FIG. 3) from the Ethernet header as the meta-data 206 of the Ethernet header. In operation 720, the flow 120 of the data may be associated (e.g., using the visibility module 100 of FIG. 1) through the network to a physical computing device associated with a user (e.g., the user 112 of FIG. 1) through the meta-data 206 of the Ethernet header (e.g., as illustrated in FIG. 3).

Although the present embodiments have been described with reference to specific example embodiments, it will be evident that various modifications and changes may be made to these embodiments without departing from the broader spirit and scope of the various embodiments. For example, the various devices, modules, analyzers, generators, etc. described herein may be enabled and operated using hardware circuitry (e.g., CMOS based logic circuitry), firmware, software and/or any combination of hardware, firmware, and/or software (e.g., embodied in a machine readable medium). For example, the various electrical structure and methods may be embodied using transistors, logic gates, and electrical circuits (e.g., application specific integrated (ASIC) circuitry and/or in Digital Signal Processor (DSP) circuitry).

Particularly, the visibility module 100, the analysis module 302, the type module 304, the classification module 306, the extraction module 308, the streaming module 310, the index module 312, the compliance module 314, the organization content module 316, the last recently used data module 318, the header extraction module 320, the Ethernet header module 322, the IPv4 header module 324, the TCP header module 326, the UDP header module 328, the IPv6 header module 330, and the ARP header module 332 of FIG. 1-7 may be enabled using software and/or using transistors, logic gates, and electrical circuits (e.g., application specific integrated ASIC circuitry) such as a visibility circuit, an analysis circuit, a type circuit, a classification circuit, an extraction circuit, a streaming circuit, an index circuit, a compliance circuit, an organization circuit, a last recently used data circuit, a header extraction circuit, an Ethernet header circuit, an IPv4 header circuit, a TCP header circuit, an UDP header circuit, an IPv6 header circuit, and an ARP header circuit, and other circuit.

In addition, it will be appreciated that the various operations, processes, and methods disclosed herein may be embodied in a machine-readable medium and/or a machine accessible medium compatible with a data processing system (e.g., a computer system), and may be performed in any order (e.g., including using means for achieving the various operations). Accordingly, the specification and drawings are to be regarded in an illustrative rather than a restrictive sense.

What is claimed is:

1. A method, comprising:
identifying a packet having a header and a payload in a flow of a data through a network;
classifying the header of the packet in a type of the header;
determining an algorithm to extract a meta-data having information relevant to network traffic visibility based on the type of the header;
extracting the meta-data from the header; and
streaming the meta-data to a storage device.

2. The method of claim 1 wherein the meta-data is stored in a database of the storage device, and wherein the storage device is limited in a storage capacity (e.g., to 16 terabytes of data).

3. The method of claim 2 further comprising applying a last recently used algorithm to discard information from the storage device when storage device is limited in the storage capacity.

4. The method of claim 1 further comprising:
determining that the type of the header is an Ethernet header;
extracting at least one of an Ethernet source address, an Ethernet destination address, and an Ethernet protocol from the Ethernet header as the meta-data of the Ethernet header; and
associating the flow of the data through the network to a physical computing device associated with a user through the meta-data of the Ethernet header.

5. The method of claim 1 further comprising:
determining that the type of the header is an IPv4 internet protocol header;
extracting at least one of a source IP address, a destination IP address, an IP flag, a header length, an IP protocol, an IP options (e.g., out of bound messages, may depend on application), and a payload length from the IPv4 internet protocol header as the meta-data of the IPv4 internet protocol header;
determining which entity on the network (e.g., which website, which server, etc.) was accessed through the meta-data of the IPv4 internet protocol header; and
determining how much total traffic was sent by a particular user of the network in a session by analyzing the meta-data of the IPv4 internet protocol header and other IPv4 internet protocol headers.

6. The method of claim 5 further comprising determining that the type of the header is an IPv6 internet protocol header;
extracting at least one of a source IP address, a destination IP address, a next header, and a payload length from the IPv6 internet protocol header as the meta-data of the IPv6 internet protocol header;
determining which entity on the network (e.g., which website, which server, etc.) was accessed through the meta-data of the IPv6 internet protocol header; and
determining how much total traffic was sent by a particular user of the network in a session by analyzing the meta-data of the IPv6 internet protocol header and other IPv6 internet protocol headers.

7. The method of claim 1 further comprising:
determining that the type of the header is a transfer control protocol (TCP) header;
extracting at least one of a source port, a destination port, a sequence number, a sequence number, an acknowledgement number, a TCP flag, and a TCP option from the TCP header as the meta-data of the TCP header;
determining what kind of activity a particular user engaged in (e.g., web traffic, ftp, instant message traffic, etc.) through an analysis of the meta-data of the TCP header and other headers;
permitting a reconstruction of an artifact (e.g., a file, a photo, etc.) through an analysis of the meta-data of the TCP header.

8. The method of claim 1 further comprising:
determining that the type of the header is a user datagram protocol (UDP) header;
extracting at least one of a source port, a destination port, a sequence number, and a payload length from the UDP header as the meta-data of the UDP header;
determining that a particular user engaged in (e.g., one line game playing, name server lookups, hacking, etc.) an unauthorized activity through an analysis of the meta-data of the UDP header and other headers;
permitting a reconstruction of an artifact (e.g., a file, a photo, etc.) through an analysis of the meta-data of the UDP header.

9. The method of claim 1 further comprising:
determining that the type of the header is an address resolution protocol (ARP) header;
extracting at least one of a broadcast data from the ARP header as the meta-data of the ARP header;
determining that a particular user engaged in (e.g., ARP poisoning, etc.) an unauthorized activity through an analysis of the meta-data of the ARP header and other headers;
reconstructing the unauthorized activity (e.g., for attack prevention and attack detection) through an analysis of the meta-data of the ARP header.

10. The method of claim 1 further comprising storing the meta-data and other meta-data of the flow of network data based on a compliance requirement (e.g., CALEA).

11. The method of claim 10 wherein the data of the network flows through a local area network.

12. The method of claim 1 in a form of a machine-readable medium embodying a set of instructions that, when executed by a machine, causes the machine to perform the method of claim 1.

13. A method, comprising:
identifying a packet having a header and a payload in a flow of a data through a network;
classifying the header of the packet in a type of the header;
determining an algorithm to extract a meta-data having information relevant to network traffic visibility based on the type of the header;
extracting the meta-data from the header;
determining that a storage device does not have capacity to store the meta-data; and
discarding a last recently used data when the storage device does not have capacity to store the meta-data such that a sliding window is formed in the storage device that discards the last recently used data when making room for the meta-data and future meta-data.

14. The method of claim 13 further comprising streaming the meta-data to a storage device.

15. The method of claim 14 wherein the meta-data is stored in a database of the storage device, and wherein the storage device is limited in a storage capacity (e.g., to 16 terabytes of data).

16. The method of claim 13 further comprising:
determining that the type of the header is an Ethernet header;
extracting at least one of an Ethernet source address, an Ethernet destination address, and an Ethernet protocol from the Ethernet header as the meta-data of the Ethernet header; and
associating the flow of the data through the network to a physical computing device associated with a user through the meta-data of the Ethernet header.

17. A visibility module, comprising:
an analysis module to analyze a packet having a header and a payload in a flow of a data through a network;
a type module to classify the header of the packet in a type of the header;
an classification module to determine an algorithm to extract a meta-data having information relevant to network traffic visibility based on the type of the header;
a extraction module to extract the meta-data from the header; and
a streaming module to transfer the meta-data to a storage device.

18. The visibility module of claim 17 wherein the meta-data is stored in a database of the storage device, and wherein the storage device is limited in a storage capacity (e.g., to 16 terabytes of data).

19. The visibility module of claim 17 further comprising a last recently used data module to apply a last recently used algorithm to discard information from the storage device when storage device is limited in the storage capacity.

20. The visibility module of claim 17 wherein the data of the network flows through a local area network, and wherein the visibility module is a storage appliance coupled to a gateway (e.g., router) of the local area network.
